(19) United States
(12) Patent Application Publication
(10) Pub. No.: US 2019/0067958 A1
(43) Pub. Date: Feb. 28, 2019

(54) Hybrid Power Supply Unit For Audio Amplifier

(71) Applicants: Charles Zimnicki, Lake Zurich, IL (US); Walter Raczynski, Arlington Heights, IL (US)

(72) Inventors: Charles Zimnicki, Lake Zurich, IL (US); Walter Raczynski, Arlington Heights, IL (US)

(21) Appl. No.: 16/104,787

(22) Filed: Aug. 17, 2018

Related U.S. Application Data
(63) Continuation-in-part of application No. 14/678,505, filed on Apr. 3, 2015, now abandoned.

(51) Int. Cl. H02J 7/00; H03F 3/185; H03F 3/21; H02J 7/02

(52) U.S. Cl. CPC H02J 7/0013; H03F 3/185; H03F 2200/03; H02J 7/022; H03F 3/21

(57) ABSTRACT

A system and method for using a circuit for providing power from one or more battery packs charged by a AC-mains-provided electrical connection and which supply power to a hi-power, non-portable audio amplifier. The system includes a power supply sized to satisfy long time-basis average demands, a battery pack and with a controller which buffers or back-ends a power supply which is not otherwise capable of satisfying the variable load peak demands that an audio source imposes on the amplifier, while still maintaining a substantially constant battery charge over an extended period of time.

### RELATED APPLICATION DATA

This application is a continuation in part of application Ser. No. 14/678,505, filed Apr. 3, 2015, which in claims priority to provisional patent application No. 61/975,249, filed on Apr. 4, 2014.

### FIELD OF THE DISCLOSURE

The present disclosure relates to a system and method for the more efficient supply of power to an audio amplifier system. In particular, the present disclosure relates to the use of batteries on similar electrochemical energy storage units for instantaneously meeting peak power demands in an audio amplifier system.

The present disclosure relates to a system and method for the more efficient supply of power to an audio amplifier system. In particular, the present disclosure relates to the use of batteries for equalizing power demands in a high-end/high-power, mains-connected audio amplifier system over a substantial time period (on the order of several seconds or minutes).

### BACKGROUND

Traditionally, in an audio amplifier—electrolytic capacitors are used for decoupling of the power supply from the rest of the amplifier's circuitry. High power audio amplifiers, and especially class-D amplifiers, are very different from an average electrical circuit because of the way they use power (as compared to, for instance, an electrical heater or even a more traditional audio amplifier such as a Class A or Class AB amp. The power needed for a high-efficiency Audio Amplifier is highly dependent upon the instantaneous power fed to the speakers, which in-turn is predicated on the instantaneous level of the audio signal fed to the amplifier. The highly inconsistent and “unpredictable” nature of music amplitude means that the peak power demands will be many times greater than the average power delivered from the amplifier to the speakers.

The above phenomenon has forced the amplifier designer to use “over-sized” power supplies with peak power many times greater than average power. This “overdesign” has a large impact on power supply efficiency because the efficiency of a power supply is defined by a ratio of output power to the total power consumed by the power supply. With almost all power supplies, this ratio is not constant, and the ratio decreases greatly at low power levels. For a hypothetical example: a 100 W power supply may be 80% efficient at 80 W output but only 30% efficient at 10 W output. This effect is dictated by power losses that do not scale with the output power. Often the losses of the power supply stay more or less fixed regardless of the power drawn, so listening at low power levels is even more inefficient in an absolute sense.

These inherent non-linear power supply losses have a very real impact on the achievable efficiency of an audio amplifier power supply. For example, assume that the average power consumed by an audio amplifier at typical listening levels is 100 W but a 1000 W power supply is used to mitigate the power surges demanded by the audio signal that occur during normal listening. Even a very efficient power supply of this size can easily have losses that are on the order of 100 W. From this example we can see that the combined efficiency of a system may only be 50% as the audio power that is delivered to the speakers is comparable to the power supply losses. The efficiency would be progressively lower as the listening power is decreased because the low level audio power would be much lower than the losses of the power supply.

To build an efficient power supply specifically geared for a high-power, mains-connected audio amplifier, such a power supply could just deliver the same power as the average music power. However, in order to provide such a power supply that still delivers the instantaneous (peak) demands inherent in a music signal, the present disclosure describes an improved decoupling network which will store enough energy to average (or equalize) the power demands. Thus, there is a need for an improved decoupling network for providing a more efficient power supply for an audio amplifier system.

There are two factors that determine the energy storage needed for the decoupling network: one is related to the time constant which determines how long we need to store the energy between the power surges inherent in audio signals: the other is related to the periodic nature of AC (mains) power. Discarding, for the moment the first factor the indeterminate nature of the audio signal!: if the power supply drain is constant, the energy storage time needs to be sufficiently long to hold the energy between pulses of rectified AC, normally on the order of 8 to 10 ms (because rectified AC is either 50 or 60 Hz in most of the world).

Because of the sinusoidal nature of alternating current, the AC line is unable to deliver power when the sinusoid of its waveform crosses zero volts.

A mains-powered audio amplifier power-supply topology is presented that replaces the electrolytic-capacitor-based energy storage elements found in the present art with electrochemical-battery-based storage elements. Numerous, significant advantages will be presented.

### BACKGROUND OF PRIOR ART

Simple power supply designs that use diode rectifiers will have the highest demand for energy storage because they charge energy storage devices (capacitors) only for a short amount of time with each AC cycle. Designs utilizing PFC (power factor correction) can charge capacitors throughout the AC cycle. However, because the current needs to be uniformly scaled with voltage in those designs, the available power varies greatly throughout the AC cycle. Because of this, the energy storage requirement for PFC designs is only somewhat lower as compared to rectifier-based designs.

With audio amplifiers, and especially high-power audio amplifiers, the need for energy storage greatly increases because of the non-constant and irregular or aperiodic power demand of the audio amplifier, as it responds to varying audio signals.

To derive the greatest benefit from music power averaging, the energy storage time must be greatly extended beyond the range reasonably realizable with capacitors because music power requirements are “random” or aperiodic in nature and do not follow a specific (or predictable) form. Moreover, music peak power can dramatically change over the period of many seconds or minutes. Generally, a longer time constant energy storage mechanism would result in “better” (or more efficient) averaging, resulting in lower average power level required of the power supply.

If one skilled in the art wanted to create a power supply with output power “matched” to the average power consumed by audio amplifier, the energy storage requirements would have to be at least a decimal order of magnitude higher (or several) than that which is provided by an typical power supply found in equipment of the current art.

Because instantaneous and (very short-time-scale) average power demands of audio are orders of magnitude greater than the average power consumed over long timescales (say greater than one second); power supplies of the existing art are poorly suited for the tasks of:
providing a wide range of on-demand power
keeping the efficiency high
being able to realize both of the above at relatively low cost and small size

Since the advent of electronic amplification of audio signals: power-supplies that support audio amplification circuits have incorporated electrostatic (reactive) circuit elements that store energy obtained during AC line peaks to compensate for intervals where the AC line provides little or no energy to drive the amplifier. These reactive circuit elements, which are generally of the class of components known as electrolytic capacitors provided an easy means to “hold-up” the circuit when the AC waveform was near or at 0V.

A Typical Power Supply for an Audio Amplifier:
Is rated for peak audio power because it must supply sufficient power during peak demand (for example a drum beat).
Uses capacitors for energy storage. The energy storage medium must be part of or immediately follow the power supply because the Energy Storage Medium must filter (equalize, decouple) non-constant AC power source, being 50 or 60 Hz. Therefore, the energy must be stored to provide constant (DC) power even though the mains source provides AC, which is non-constant.
In addition to above: the Energy Storage Medium must filter (equalize, decouple) non-constant power load due to the unpredictable, aperiodic varying nature of a musical waveform.

There exist several ways to reliably provide stable power to an audio amplifier from mains-supplied power, as discussed by reference to the following example:

Example—Power Supply Requirements of a Typical Audio Amplifier:

A typical amplifier producing 250 W of RMS power into a typical 4-ohm speaker will need to source about 8 A RMS. Converting, the peak-to-peak current demand will be about 22 A. Because a power supply has non-linear (or non-resistive) characteristics: the peak-to-peak current is actually closer to the real peak power supply current rather than the RMS current. Let's assume that the lowest frequency of the sound produced by this amplifier is 20 Hz. Even if we assume that the music does not vary in amplitude over time—being a continuous 20 Hz tone, the power supply would still need to provide power that varies with the 20 Hz signal—therefore, the peak consumption would occur every 50 ms.

A first known approach to satisfying the peak demands of an audio amplifier will be called the “brute force solution,” which can be effective but it is costly, very inefficient, very large and heavy. Using the hypothetical example values from above, to supply 22 A at 80V the power supply would need to be rated on the order of 2 kW. P=22 A*80V=1760 W. Furthermore, there is an energy loss penalty to be paid. Even if the power supply was 90% efficient, the loss would translate to roughly 176 W of power, which would be comparable to the 250 W power output of the amplifier (which in turn would make the total solution very inefficient). Such solution would definitely not be considered environmentally friendly. In addition, such an over-sized power supply would be much larger and heavier physically, making a solution unattractive (both from a cost and aesthetics point of view). Finally, the cost of “oversizing” the power supply by almost 10× makes it a poor solution for a product produced by for a profit-driven company and customers that wish to be responsible consumers of energy.

A further known solution involves decoupling, e.g., using a bank of capacitors with substantial capacitance value to temporarily store energy from the power supply to satisfy instantaneous demands of the audio amplifier. The basic relationship between voltage and current in a capacitor is I=C*dV/dt. Therefore, the capacitance value can be calculated as follows:

C=I*dt/dV

To calculate the capacitance required for effectively decoupling an audio amplifier, we need to consider two values:
dV, which, in the case of an audio amplifier, would be the voltage droop on the power supply terminals (rails) when the amplifier is delivering power to the speakers that approaches its power supply rating (during periods of high demand).
dt, which is the maximum time necessary to store the energy from the power supply in order to satisfy the amplifier's demands. However, by increasing the decoupling network effective storage time, more can be gained in terms of power supply scaling. A longer storage time results in lower power requirements for the power supply unit while still producing the same loudness level music at the speaker.

Through some basic calculations, we can see that it would be difficult and costly to provide a capacitor bank sufficient for storing energy over a substantial amount of time. For illustration refer to the example of the 250 W amplifier (considered a modest power audio amplifier by an audiophile), presented above with 80V rail voltage and 22 A peak current.

Assuming a relatively large voltage droop of 5% (translating to 4V at 80V) and 22 A peak current and dt=50 ms (not uncommon in the present art), one skilled in the art can see that the required capacitance would be C=I*dt/dV=0.28 F.

Solutions employing large capacitor banks are generally more efficient than the “brute-force” solutions employing an oversized power supply. This is because using large capacitor banks can effectively decrease the size of the power supply without wasting energy, because of the very high energy efficiency of the capacitors. Nevertheless, such solutions are still physically large and costly. Using the above example even with a very modest storage time of 50 ms, the solution would already have a physical volume of about 2 liters using typical filter capacitors available today (based on 0.3 F capacitance and 80V working voltage in the referenced example). It would be impractical to build decoupling networks to provide storage times longer than 50 mS, no matter how desirable—simply because of the physical volume of such a scaled solution would be even larger.

The prior art therefore reflects a need for a compact, efficient stable power source for a power supply decoupling mechanism.

### SUMMARY OF THE DISCLOSURE

The present disclosure teaches the use of a hybrid power supply system i.e. a system using battery based decoupling network, i.e. a battery stack directly connected to the amplifier circuitry and a plugged-in or mains power supply operatively connected to the battery stack for audio amplifiers. That is, the present disclosure deals with using batteries only for short-term (minutes, not hours) energy storage, supplying the only energy source that the audio amplifier's bridges “see” in providing a power supply supported by to the main, plugged-in power source, i.e.: using batteries, such as using rechargeable lithium batteries both for the filtering of the rectified AC line voltage and to store sufficient energy to satisfy the instantaneous peak demands of the audio signal. This disclosure is not to result in a battery-operated, portable amplifier. Rather, the present disclosure teaches the use of a battery stack (or Pack) as an electrochemical decoupling network operating in conjunction with a main power supply and a controller to ensure a consistent power supply to meet the demands of the audio amplifier system.

The present disclosure teaches the use of a hybrid power supply system utilizing multi-cell rechargeable (lithium) batteries configured in series a (“Stack” or “Pack”) in order to provide an appropriate “rail” voltage as a decoupling network, the battery stack being intentionally interposed between the power supply and the connected high power audio amplifier.

That is, the present disclosure deals with using batteries only for short-term (minutes, not hours) energy storage. A short-term energy storage stack or pack as described here, in contrast to batteries used to power portable equipment, would remain connected to the mains and be optimized for operation specifically to maintain a constant state-of-charge, with the stack (or pack) appropriately configured to equalize the amplifier power drain over a sufficient time period to provide the maximum benefit in terms of the amplifier current equalization.

The circuit implementation covered in this disclosure is not intended to result in a battery-operated, portable amplifier. Rather, the present disclosure teaches the use of a battery stack as an electrochemical decoupling network operating in conjunction with a mains-based power supply and a controller to ensure a consistent power supply source of stable DC power to meet the unpredictable and aperiodic demands of the audio amplifier system.

To provide context regarding the amount of energy is available via battery, consider a typical power tool battery which today is based-upon Lithium-based chemistry, (there are a number of other chemistries that provide similar benefits and current research is leading to even better power and energy densities at an ever-increasing pace, so this discussion should not be regarded as being limited to a given chemistry but to the inherent benefits provided by electrochemical storage in the disclosed arrangements). A very typical 18650 form-factor battery with a physical size of 18 mm×65 mm has a typical capacity as of this writing of 2000 mAh or more. The discharge peak current can be as high as 100 C*, which translates to peak current of about 200 A. * C is Used to signify a charge or discharge rate equal to the capacity of a battery divided by 1 hour. Thus C for a 1600 mAh battery would be 1.6 A, C/5 for the same battery would be 320 mA and C/10 would be 160 mA. Because C is dependent on the capacity of a battery the C rate for batteries of different capacities must also be different.

This favorably compares with the aforementioned example of the power amplifier peak current requirement of 22 A. The voltage of each battery is typically on the order 4.0V, which means that one would need 20 batteries to have an energy storage solution that could assist the audio amplifier as stated in the example provided. The internal resistance of present-day 18650 cells can be lower than 5 milliOhms, which translates to a ripple voltage of about 2V on an 80V rail. The physical volume of such a storage solution would be 0.3 liters or over 6 times smaller than that which can be obtained with capacitive hold-up approaches (i.e. capacitive decoupling networks) today.

Such a battery solution compares favorably to a capacitor-bank solution. However, a more significant benefit of using the batteries is actually in the extended energy storage time. If we were to use the (above referenced) twenty 18650 cells as our energy storage solution, we could easily afford to average music power over substantially longer time constants (of seconds and even minutes as compared to the tenths tens of milliseconds that a capacitor bank can provide). The 22 A current (from our example) drawn for 1 second would be equal to 22 C, which in turn would discharge the 20*2000 mAh battery bank by approximately 0.3%.

Thus, as can be seen from the present disclosure, one advantage of the present disclosure is to provide a “hybrid” power supply for an audio system that is geared towards an average power demand, as opposed to peak power demand.

Another advantage of the present approach is to provide a hybrid power audio supply with a greater energy density than existing power supply systems. Electrolytic Capacitors have an energy density on the order of 0.001-0.003 MegaJoules/kg. Contrast this with that of current Rechargeable Batteries which are conservatively 2 to 3 decimal orders of magnitude greater in energy density per weight than that of electrolytic capacitors: A typical lithium-chemistry battery has an Energy Density of 0.5-1.0 MegaJoules/kg.

A further advantage of the present disclosure is to provide a hybrid power audio supply with improved discharge characteristics over prior approaches, because modern rechargeable batteries typically have flat discharge curves rather than the exponential decay of a capacitor.

A further advantage of the present disclosure is to provide a hybrid power audio supply with improved discharge characteristics over prior approaches.

Still a further advantage of the present disclosure is a reduction of the physical size of the audio amplifier because of the high energy density of the battery stack of the power supply unit.

Yet another advantage of the present disclosure is further reduction in size in the power supply unit because the main power supply is scaled to audio power averaged over seconds/minutes as opposed to milliseconds as with the present art.

Another advantage of the present disclosure is improved audio performance due to decreased audio noise—resulting from the reduction of the capacity of the main power supply. Assuming a switching power supply, the electromagnetic noise (unintentionally) produced is substantially proportional to the size and power of the unit.

Yet another advantage of the present disclosure is providing increased power efficiency because the main power supply “sees” a constant load. Batteries perform the job of load averaging over a substantial time, so the load appears nearly constant to the power supply. In other words, the batteries equalize power demand so now the power supply can be scaled down to its most efficient operational range.

Audio power averaged over seconds/minutes is much lower than peak power. Power supplies generally exhibit somewhat constant efficiency, for example 90% efficient power supplies are obtainable today with 10% being lost to heat. An increase in the rated power of the power supply will generally result in higher losses for the same efficiency.

Finally, another advantage of the present disclosure is the reduction in heat production because the power supply unit is better sized for the load and can operate in its “greenest” mode.

These and other advantages of the present disclosure will be better understood with reference to the following disclosure and its accompanying drawings. Note, however, that not all of the aforementioned advantages will necessarily be met in each embodiment of the present disclosure, as will be understood by those of ordinary skill in the art.

### DESCRIPTION OF THE DRAWINGS

FIG. 1 discloses an example music signal expressed as an alternating current (AC) waveform.

FIGS. 2a and 2b are graphical representations, respectively, of the relative voltage amplitude and the relative audio power of a 1.5 second music sample.

FIG. 3 shows the relative audio power graph of FIG. 2b overlaid with an audio power value of the same signal using a time constant of 10 mS.

FIG. 4a shows the relative audio power graph of FIG. 2b overlaid with an audio power value of the same signal using a time constant of 200 mS.

FIG. 4b shows a magnified version of the relative audio power graph of FIG. 4a overlaid with a line that indicates the maximum peak of the averaged power.

FIG. 5 shows an un-magnified version of the relative audio power graph of FIG. 4a overlaid with a line that indicates the maximum peak of the averaged power over the entire music clip as a fraction of the total power demand.

FIG. 6 shows a discharge curve for a capacitor as used in the prior art.

FIG. 7 shows a discharge curve for a Lithium Rechargeable Battery as used in accord with a preferred embodiment of the present invention.

FIG. 8 shows a graph comparing the relative hold-up timespan of a capacitor versus a battery in for the same physical volume in the practice of the present invention.

FIGS. 9a and 9b show, respectively, single rail and dual rail configuration preferred embodiments of the present invention.

FIGS. 9c and 9d show simplified block diagrams of preferred embodiments of FIGS. 9a and 9b in conjunctions with speakers and control circuits in accord with the teachings of the present invention.

FIG. 10 shows certain safety features for use in accordance with a preferred embodiment of the present invention.

FIG. 11 shows a unified controller for a battery stack in accordance with a preferred embodiment of the present invention.

FIG. 12 shows distributed or networked controllers for a battery stack in accordance with another preferred embodiment of the present invention.

FIG. 13 shows a schematic of a uniform single charger/manager for multiple cells recharging a battery stack in accordance with a preferred embodiment of the present invention.

FIG. 14 shows a schematic of a selective recharging (individual, networked charge managers) of batteries within a battery stack in accordance with a preferred embodiment of the present invention.

FIG. 15 shows a schematic of a Charge-Management circuit for one battery bank (i.e. pack). It is based on the microprocessor which may be used as a controller in accordance with a preferred embodiment of the present invention.

FIGS. 15a-c shows the schematic of the cell balancing network of the Charge Management circuit referenced in FIG. 15.

FIG. 15d shows the Cell Manager circuit schematic referenced in FIG. 15.

FIG. 15e shows the Battery Pack Controller circuit schematic referenced in FIG. 15.

FIG. 15f shows the Bridge Charger circuit referenced schematic referenced in FIG. 15.

FIG. 15g shows the Power Supply Conditioning circuit schematic referenced in FIG. 15.

FIG. 15h shows the Temperature Sensor Circuit schematic referenced in FIG. 15.

FIG. 15i shows the Battery Contacts circuit schematic referenced in FIG. 15.

### BRIEF DESCRIPTION OF THE PREFERRED EMBODIMENTS

Set forth below is a description of what is currently believed to be the preferred embodiment or best examples of the invention claimed. Future and present alternatives and modifications to this preferred embodiment are contemplated. Any alternatives or modifications which make insubstantial changes in function, in purpose, in structure or in result are intended to be covered by the claims in this patent.

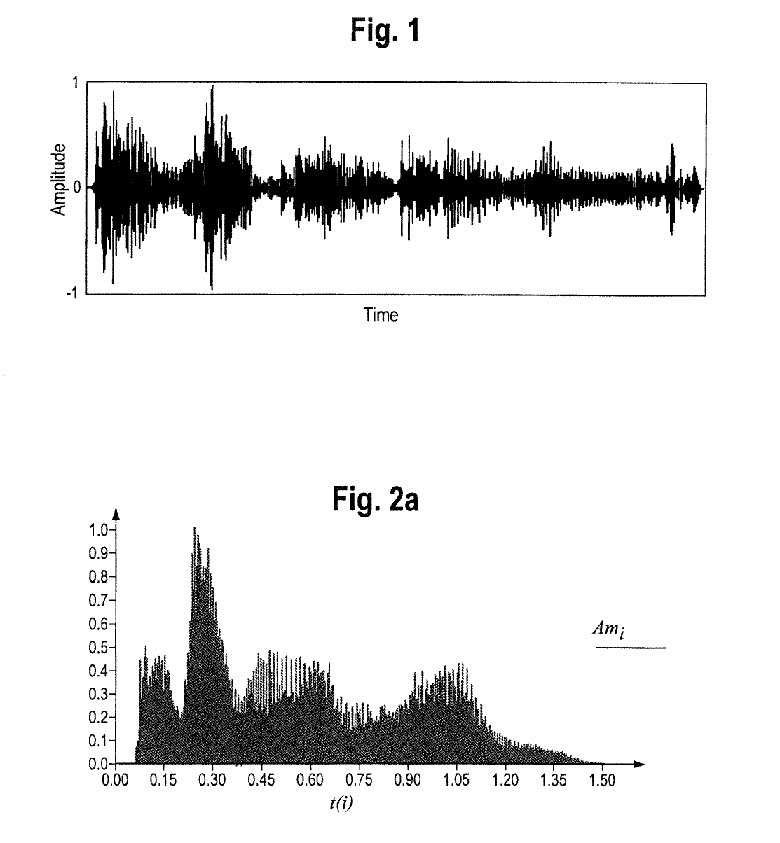

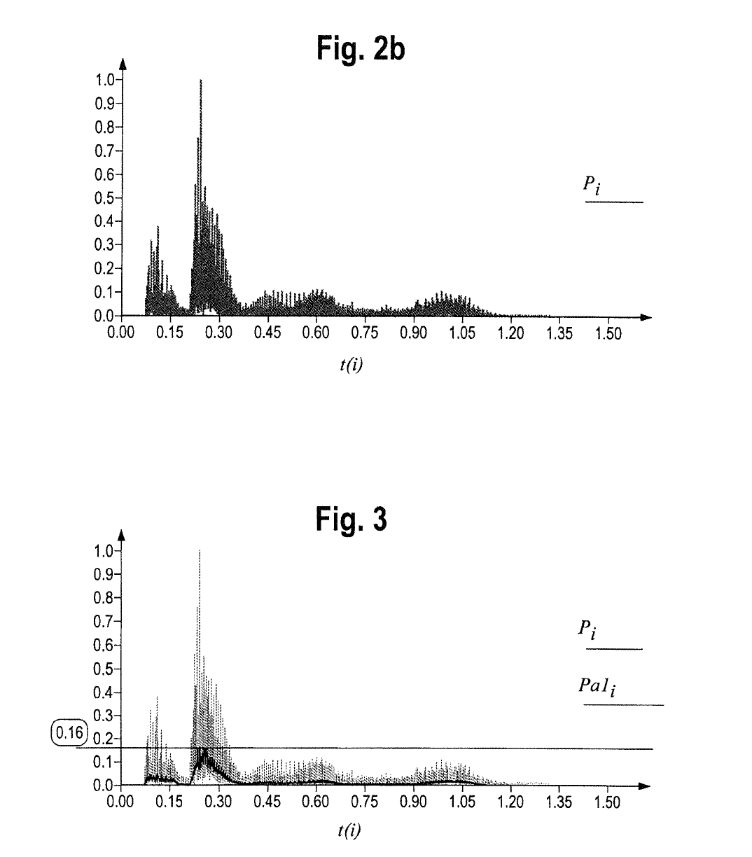

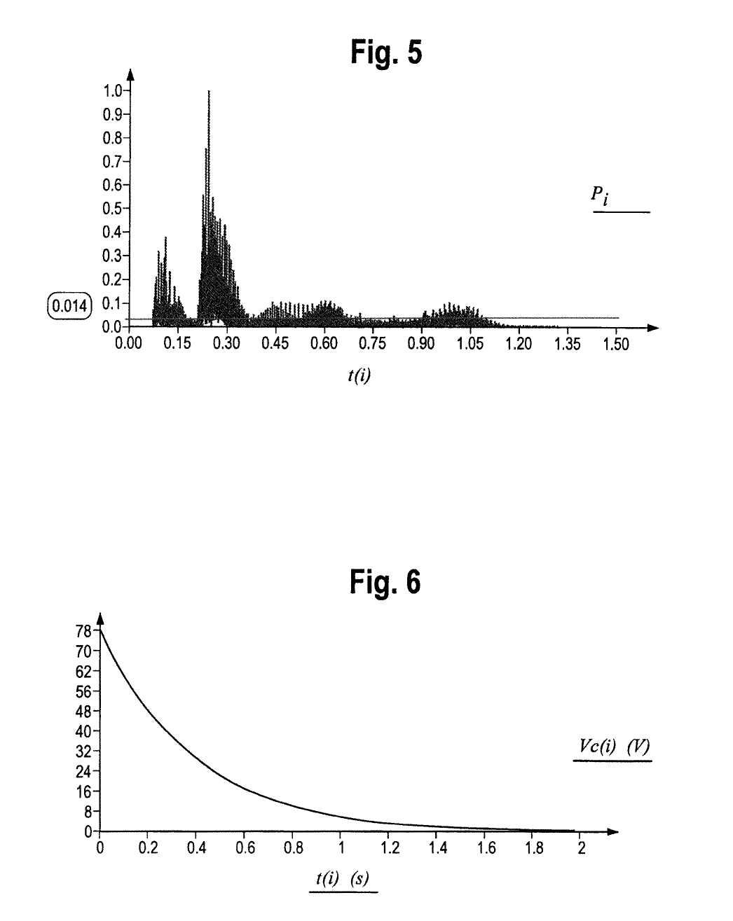

As seen in FIG. 1-5, the present disclosure involves a method and system for providing a hybrid power supply unit (i.e., a Mains-based, plug-in power supply continually replenishing an electrochemical decoupling network to an audio amplifier system. This process, as shown in FIG. 1, involves supporting a music signal, which appears as a complex, aperiodic and continuously varying AC waveform. As shown in FIG. 2a, the relative voltage amplitude of even a short (1.5 second) music sample can vary wildly. Accordingly, as shown in FIG. 2b, the relative audio power requirements for such a sample must vary even more dramatically, as the signal power is proportional to the square of the instantaneous signal voltage.

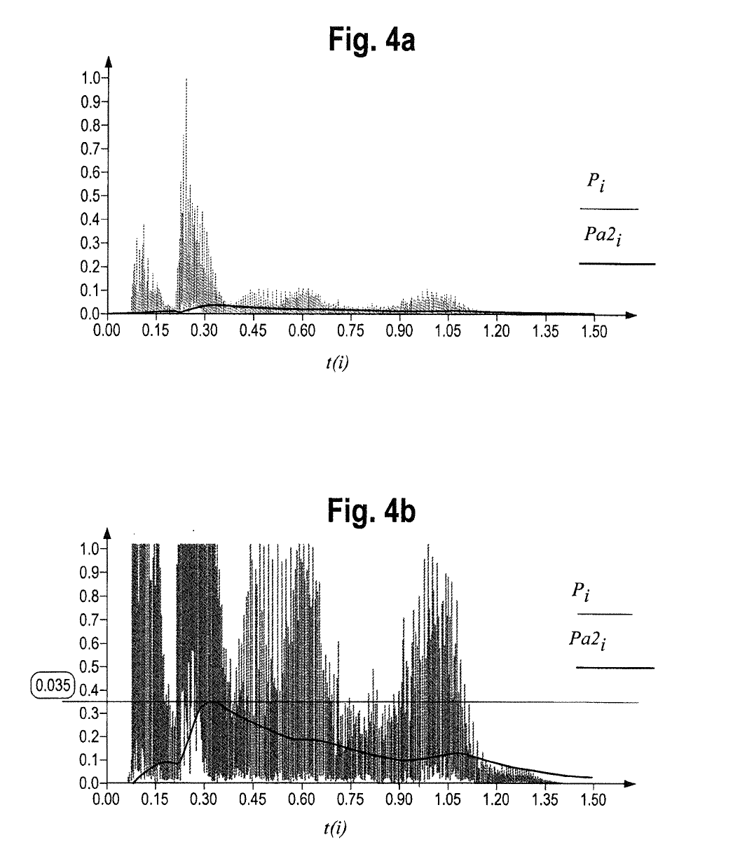

However, as shown in FIG. 3, the audio power value is much lower when averaged using a time constant (in this case a time constant of 10 mS). When this recording clip is averaged this way, the peak power of the averaged signal is 0.16 (16%) of the non-averaged signal. The fraction of the peak power required is even smaller when the time constant increases. For instance, as shown in FIGS. 4a and 4b, when the Audio Power value is averaged using a time constant of 200 mS (20 times longer that of FIG. 3), it can be seen that the maximum peak power of the averaged signal is 0.035 (3.5%) of the non-averaged signal. Moreover, the power average of the whole signal in this instance is only 0.014 (1.4%) of the peak power requirements imposed by the signal. Thus, present invention operates by providing a supplemental source (i.e., a battery stack) in line with the main power supply so as to allow the batteries to recharge continuously as needed when the mains-based power supply at a given instant is substantially incapable of supplying the instantaneous power demand of the signal. Those of skill and having the present disclosure will understand that such a battery stack is “supplemental” with respect to the configuration of the system, but that they are the sole power source visible to the audio bridge or other controller, i.e. that the battery stack is directly communicating with the load, without any intervening DC boost converter circuitry, and without any direct connection to the mains-based power supply as required by prior approaches.

The present invention preferably relies upon a typical “off-the-shelf’ AC power supply, except that the power supply can be much smaller in capacity, since it is rated for lower AVERAGE power as opposed to requiring it to be sized for PEAK power demands of the system. The energy density provided by electrochemical means (batteries) permits this longer time constant averaging and the use of substantially smaller AC to DC Power supplies. The present invention thus uses batteries to decouple the mains-based power supply from the highly varying audio load. The batteries are used to accumulate energy (supplied by the AC power supply) during low demand periods (e.g., quieter passage of the audio track), and supply the power during high demand periods (e.g., heavy bass, drums, explosions, cannonfire, etc. even during periods when the power-supply is limited by the periodic zero crossing of the AC line).

The battery lifetime of the present disclosure is optimized because the present disclosure describes typically operating the batteries at a nearly constant charge level and the re-charging currents required are substantially less than that required with a deeply-discharged cell. The present invention never deeply discharges any cell and in fact the cells are always maintained substantially at their optimum voltage. A relevant illustrative example might be that a battery usually lasts a lot longer in a cordless landline phone (which is normally plugged in) than in a cell phone (which is normally not plugged in, and is discharged substantially deeper and required to recover its capacity during each recharge cycle).

Thus, one important characteristic of the batteries of the present invention must be the ability to maintain a substantially optimum, near constant voltage for a longer period of time. Unfortunately, a capacitor has unsatisfactory characteristics in this regard. As shown by FIG. 6, with a load characterized by a constant resistance, a capacitor's voltage will follow an exponential decay curve according to the equation below, where Vi is the initial voltage on a capacitor:

$${V}_{c} = {V}_{i} ( {e}^{\frac{- t}{RC}} )$$

The discharge curve is undesirable because with the constant load, the loss of capacitor charge and therefore capacitor voltage) occurs suddenly, with the highest slope of the curve at the capacitor's working voltage. An audio signal can easily be perceptibly altered by this discharge characteristic. This is called ripple.

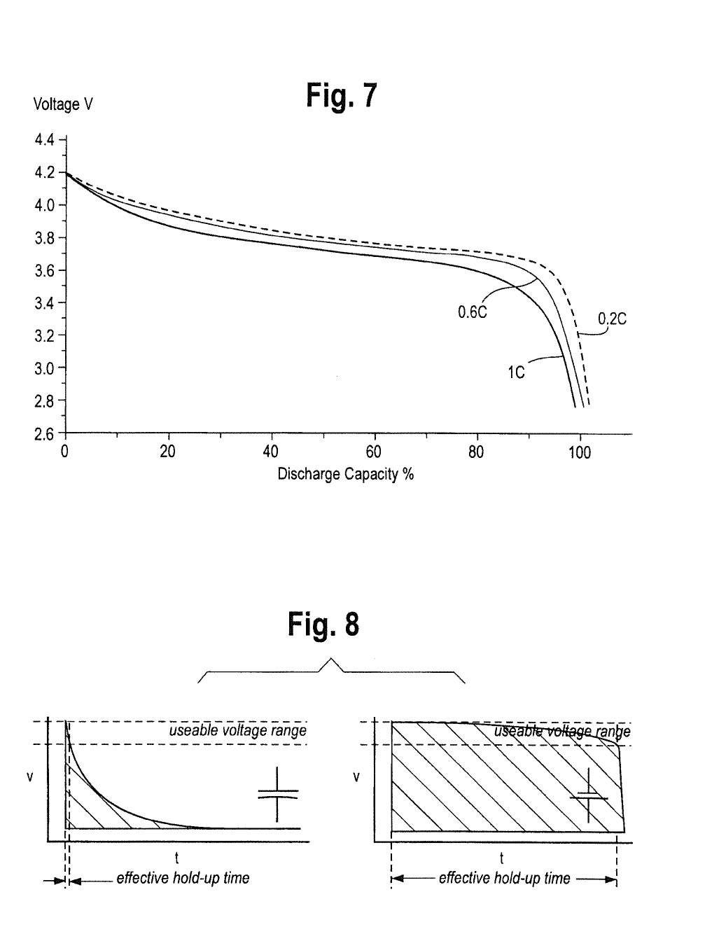

Unlike the characteristic discharge curve of a reactive circuit element (capacitor), an electrochemical hold-up element as exampled by a Lithium battery has a very flat discharge curve, as shown in FIG. 7. This discharge curve is beneficial because small changes in the battery charge state do not result in high voltage ripple. As regards voltage-dependent variables, such as the gain of an amplifier in the practice of the present disclosure, the usable range of voltage is quite restricted when using capacitive hold-up means. Thus, as shown in FIG. 8, the differences between electrostatic (e.g., capacitors) and electrochemical storage means (e.g., the rechargeable batteries of the present disclosure) for “holding-up” a voltage-critical circuit become significantly more pronounced.

Furthermore, because worldwide concerns over energy consumption (which have led to innovations such as electric cars and hybrid vehicles) there are recent and substantial ongoing developments in electrochemical energy storage technologies that have resulted in electrochemical storage means orders of magnitude more energy dense than electrolytic means, with advances reported in the scientific journals on a daily basis. The pace of this change is actually increasing, favoring electrochemical energy storage over electrostatic means because of this widening gulf.

Since the total available energy (hold-up) capabilities of an electrochemical circuit element is now orders-of-magnitude greater than that of an electrostatic element: the size of the AC-DC power supply that charges the storage element may be dramatically reduced, resulting in substantial system efficiency and form-factor advantages.

While even existing supercapacitors power density is generally 10 to 100 times as great as that of a battery, they only have energy densities that are approximately 1/10^{th} that of a conventional battery. (Power density combines energy density with the speed at which the energy can be delivered to the load. This makes charge and discharge cycles of supercapacitors much faster than batteries.) Even conventional batteries still have about ten times the capacity of supercapacitors, and as stated above: because demands for EV and other portable power applications is driving intense R&D into rechargeable batteries—batteries are improving both in capacity and lifetime rapidly.

Other disadvantages of using electrostatic elements, even supercapacitors, as hold-up devices for the power rail(s) of an audio amplifier in the present disclosure include:

1) Low Energy Density
The amount of energy stored per unit weight in capacitors is significantly lower than that of electrochemical batteries (3 to 5 W-h/kg, although 85 W-h/kg has been achieved in the lab[12] as of 2010 compared to 100 to 250 W-h/kg for a lithium-ion or LiFeP04 battery).

Furthermore, since the power-supply can be now reduced by employing high energy density electrochemical means: the electrical noise content of the power supply can be further reduced, which significantly improves the measurable sonic quality of the overall amplifier solution. Better audio results from this efficiency-enhancing feature.

One traditional advantage of the Electrolytic capacitor over the rechargeable battery that teaches away from the use of batteries is the working life, at least as can be obtained with commonly available components in typical applications. That is, electrolytic Capacitors can tolerate many more charge/deep discharge cycles than batteries, even if the difference in energy storage capacity is accounted for. This might be a prohibitive factor when used in demanding or high-duty cycle applications. This is not a concern for audio applications.

Audio amplifiers, and especially high power/high quality amplifiers, do not operate with such a high duty factor. They are mostly used non-continuously, as in residential settings for personal entertainment. Of more importance is that the capacity and replenishment parameters can be balanced in such a manner as to never deeply discharge the batteries, further prolonging the life of the cells. Such is the case with hybrid vehicles, where the life of the batteries can be equal to the anticipated life of the vehicle. The audio amplifier, because the charge-discharge profile is even less demanding than that of a hybrid car is an even more favorable target for batteries and thus electrochemical batteries, not capacitors, are believed to be a necessary structure for the power supply unit of the present disclosure.

Batteries are available today comprised of differing fundamental electrochemical compositions. Each battery “Chemistry” results in a different Cell Voltage (and other characteristics). Several examples of Lithium-based batteries for practicing embodiments of the present invention are illustrated in the following table:

| Chemistry | Cell V |
|---|---|
| Li—MnO2 | 3 |
| LiFeP04 | 3.2 |
| LiNiCoMn | 3.7 |

Other very promising Lithium alternatives are on the horizon, such as Sodium ion, Sodium Nickel Chloride, Potassium-ion, Aluminum-ion to name a few. That is, the present invention should not be viewed as somehow constrained to Lithium battery chemistries as it anticipates these storage developments and is adaptable to utilize them as they mature from the laboratory to the market. Battery research has attracted many industries' attentions and the pace of research is very high with no signs of slowing.

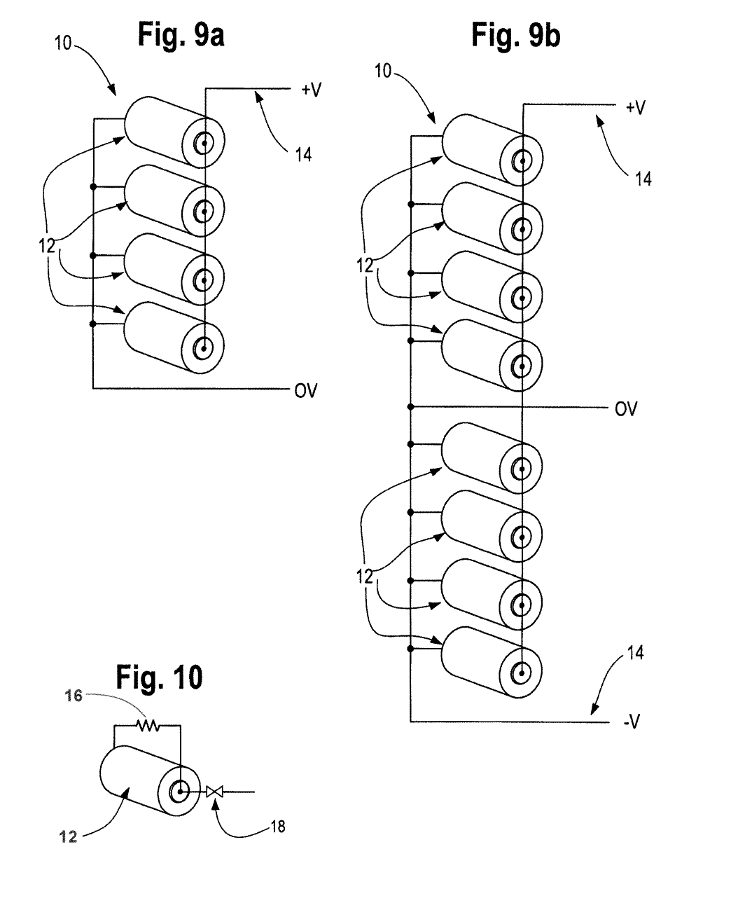

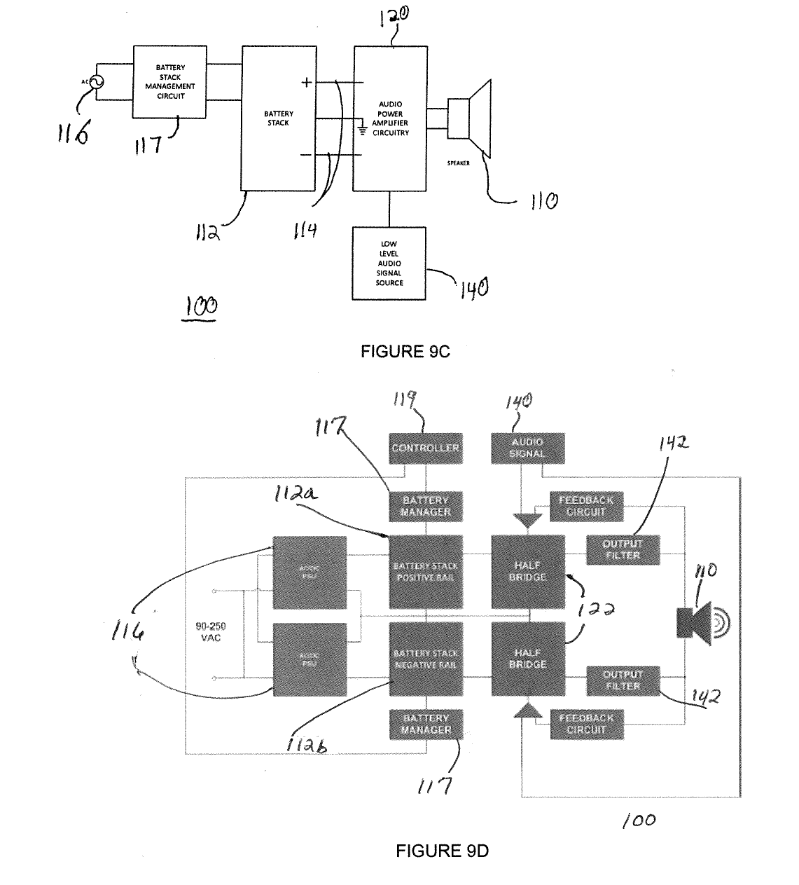

Since a given battery cell's chemistry is unlikely to provide a high-enough voltage to cause sufficient loudspeaker excursion in all but the smallest audio amplifiers, as shown in FIGS. 9a and 9c, the present disclosure involves a system, 10 which combines one or two series-strings (or “stacks”) of batteries 12, arranged so as to provide the appropriate “Rail” voltage or voltages to the Audio Amplification Power Stage(s) as follows:

Each of the configurations in FIGS. 9a and 9b battery power source maintained a regulated AC/DC power supply (not shown). The version shown in FIG. 9a is “Single Rail” battery stack 12 maintained by a single, regulated AC/DC power supply through wires 14. The wires 14 leading off to the right are tied to the DC Power supply and to an audio bridge, called a half bridge, with a Class D amplifier (not shown). By contrast, FIG. 9b shows a “Dual or Split Rail” battery stacks 12 that are fed via wires 14 by two, stacked, regulated AC/DC power supplies. Using multiple “stacks” can thus support the positive and negative DC voltages required by an audio power amplifier. If the voltage available from the Single Rail power supply is IV, the voltage available from the Split or Dual Rail supply is 2V. The wires 14 leading off to the right are tied-to one or two DC Power supply (supplies) AND to an audio bridge, called a full or H bridge, with a Class D amplifier (again, not shown).

FIG. 9c shows a larger system 100 showing the system of FIGS. 9a and 9b in operation with a speaker 110, The battery stack is) 112 are maintained by a regulated AC/DC power supply 116 through wires 114 to the audio power amplifier circuity 120 comprising, in this example of at least one audio amplifier bridge. This audio power amplifier circuity 120 receives power from the battery stack is) 112 and receives the low level audio signal source 140 i.e.—the music signal”) to provide the output to the speaker 110 at the desired volume. Eliminating the DC boost converters found in prior approaches that rely on using a battery and ac power supply components with the Direct Battery Drive of the present embodiment also the overcomes the inability of existing transformer-capacitor or inductor-capacitor networks alone to efficiently deliver energy to an audio power amplifier due to the aperiodic energy demands of the audio signal source.

FIG. 9d is a further, more specific variant of the system 100 shown in FIG. 9c. In this embodiment, the battery stacks 112a and b are negative and positive rail battery stacks. respectively, which are each fed by AC/DC power supply units 116 which convert the power to direct current to maintain charge in the stacks. Additionally, the battery stacks and/or each individual battery in the stacks includes a battery manager 117, which interfaces with a controller 119 to provide and use information about the status of the batteries, as detailed below. Similar to FIG. 9c each half bridge circuit 122 receives power from one of the battery stacks 112a-b and receives the low level audio signal source 140 and directs the amplified signal through output filters 142 to provide the output to the speaker 150 at the desired volume.

Additionally, the batteries 12 may preferably include additional components or circuitry to transduce the state-of-health of each cell, and to provide protection via the use of thermistor beads 16 and current based fuses 18, as shown in FIG. 10. Thermistor bead 16 is a structure known to those of skill in the art for triggering that a malfunction has occurred the battery 12 supply, while the current based fuse 18 is a structure which can activate when too much power being provided by the battery 12, i.e., above a predetermined threshold.

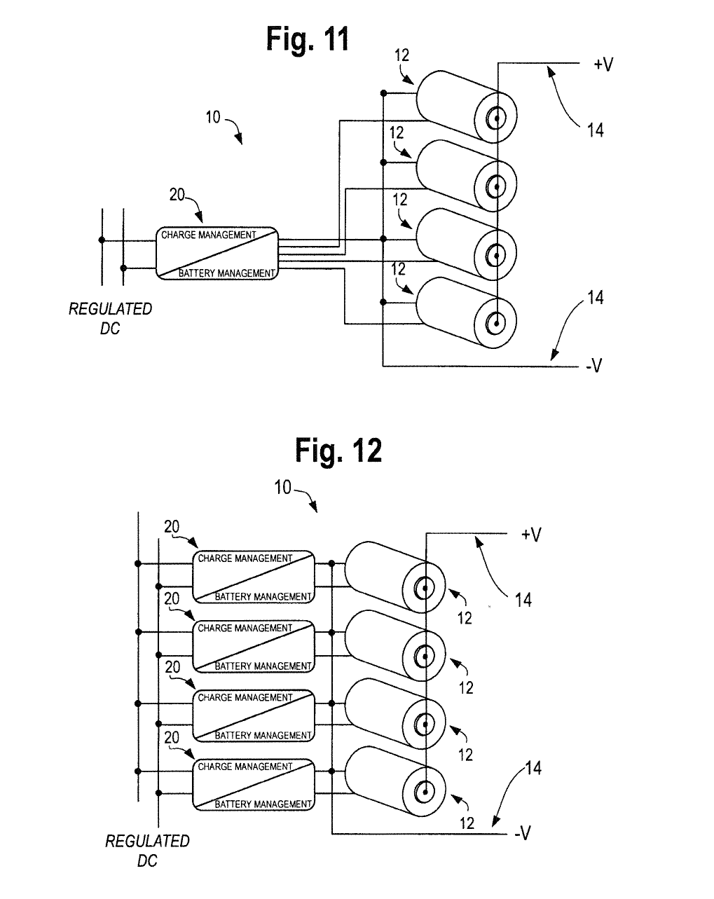

The implementation of a system 10 using a battery-decoupled power supply unit with the hold-up circuit as shown in FIGS. 9-10 would also require a control system 20 using the elements or equivalent circuitry in at least one of the alternatives as shown in FIGS. 11-15.

One preferred embodiment of a system 10 including a controller for accomplishing the hold up circuit function (i.e., the maintenance of adequate power reserve in the batteries 12) of the present disclosure is shown in FIG. 11. This embodiment leverages multiple-cell charge and health monitoring circuit elements (depicting a series string of 4 batteries for simplicity), using a single point-of-control controller 20. The controller 20 is connected to the batteries 12, and may optionally be connected to the load, e.g., the controller bridge of the amplifier (not shown). The controller 20 can work to maintain an adequate, substantially constant charge level over an extended period of time (e.g., at least one minute), such as by monitoring the given voltage level in a particular battery 12 to see whether the battery exceeds a minimum threshold or is within a given range. The controller 20 can optionally perform the functions of measuring power draw versus available power in the wire 14 (to determine the availability of power for recharging the batteries 12). Further options for the controller 20 include increasing power input from the main power supply when the battery is not charged to at least a predetermined level, or to limit the hi-power, non-portable audio amplifier load when the battery is not charged to at least a predetermined level.

Persons of skill in the art will appreciate that there exist a variety of Battery Charging integrated circuits existent today that can provide these functions as well as monitoring the state of health of the individual cells.

An alternate configuration of the system 10 means for accomplishing the same circuit function is shown in FIG. 12, which involves multiple controllers 20 (corresponding to a series string of 4 batteries 12 for simplicity) which reflects a dedicated controller 20 for providing charge and management circuitry for each battery 12.

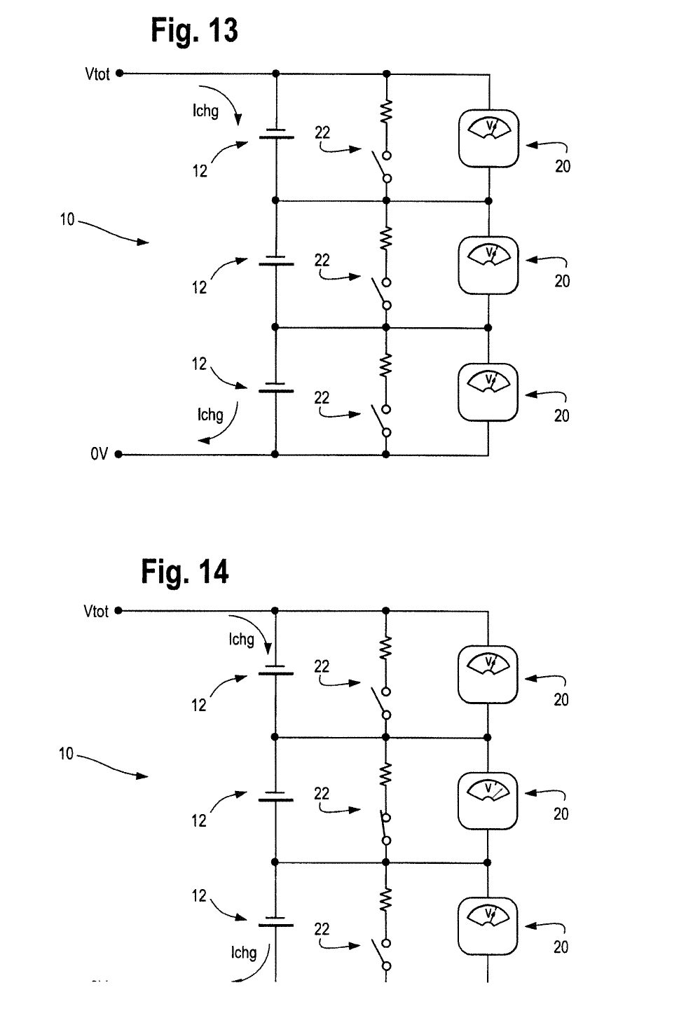

A particular function of the controller 20 is maintaining batteries 12 within a given rail or stack at the same charge level, as shown in FIGS. 13-14. During normal charging, the individual batteries 12 in the stack that comprises the “Rail” are monitored individually for their individual voltage as compared to the other cells. As shown in FIG. 13, if the voltage for each individual battery 12 is substantially identical, charging is applied to all batteries 12. However, as shown in FIG. 14, a particular cell has a lower equivalent series resistance than the others, it may charge faster than the others. The monitoring circuit of the controller 20 determines this condition in real time and shunts the charging current around that particular battery 12 and the other batteries 12 are permitted to “catch-up” to it by closing a resistor circuit 22 that corresponds to the faster charging battery 12. Thus, an even charge across all batteries 12 within the rail may be maintained.

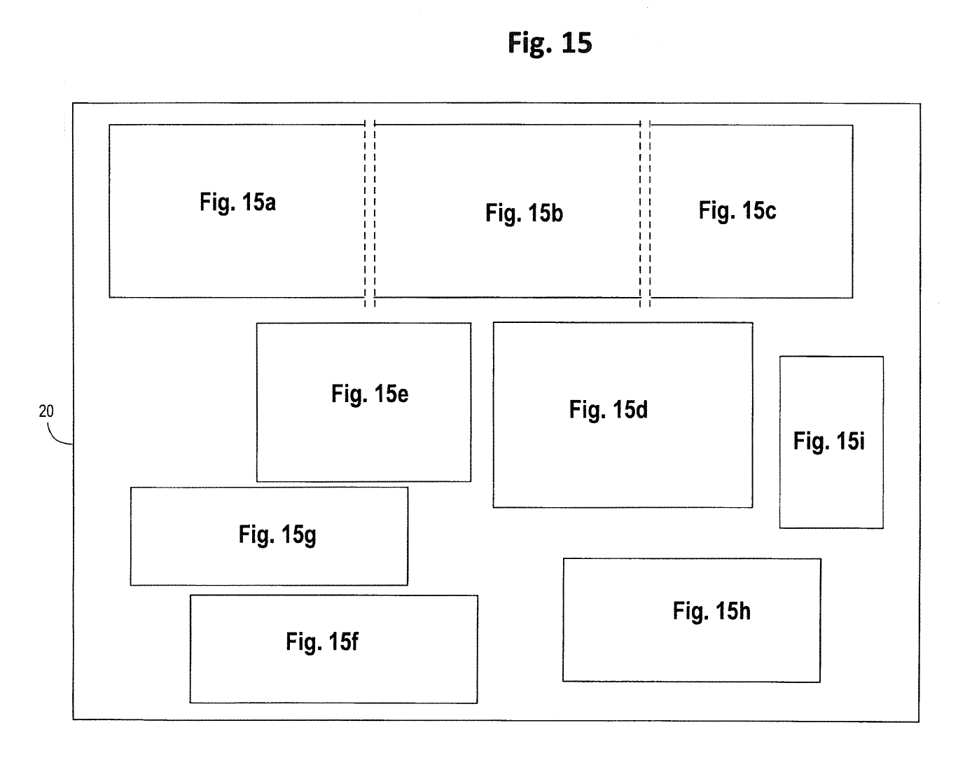

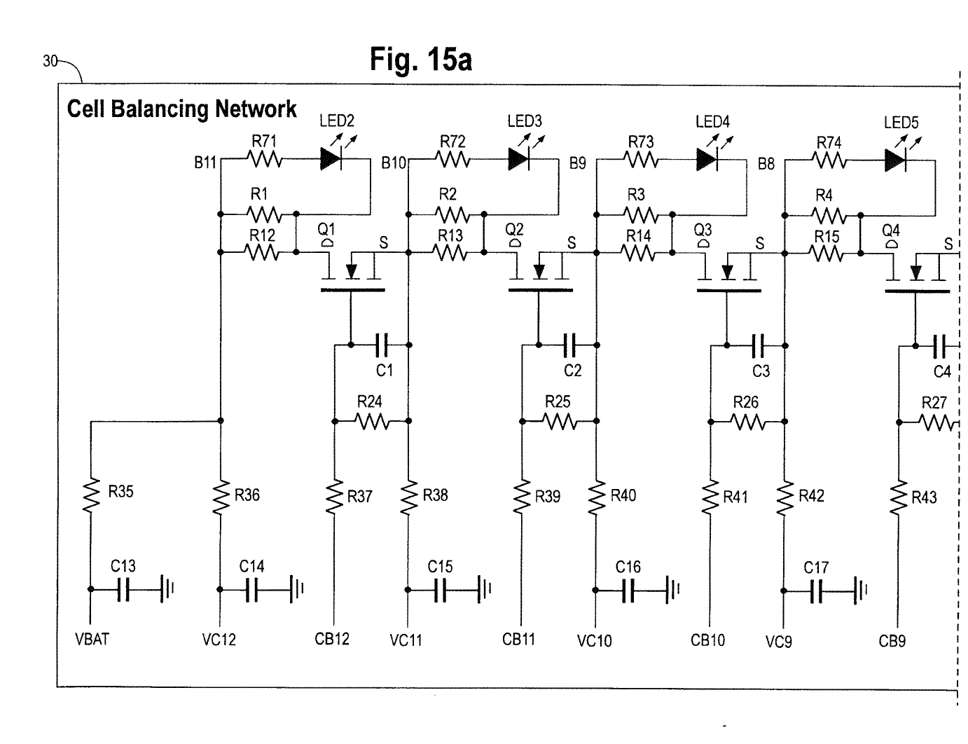

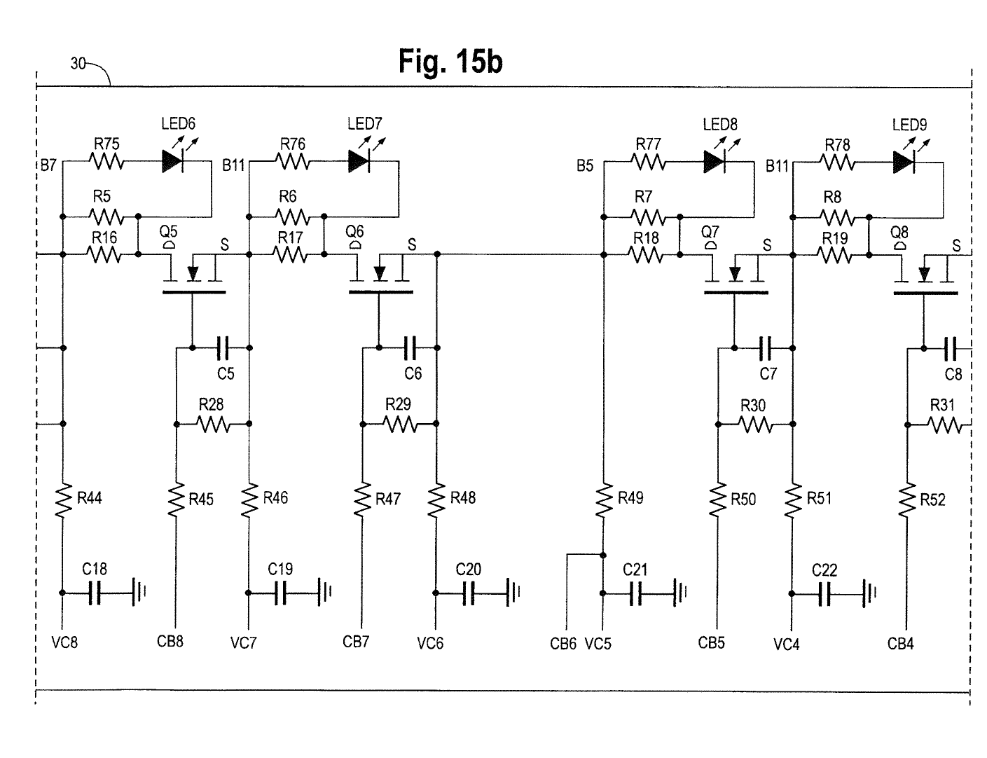

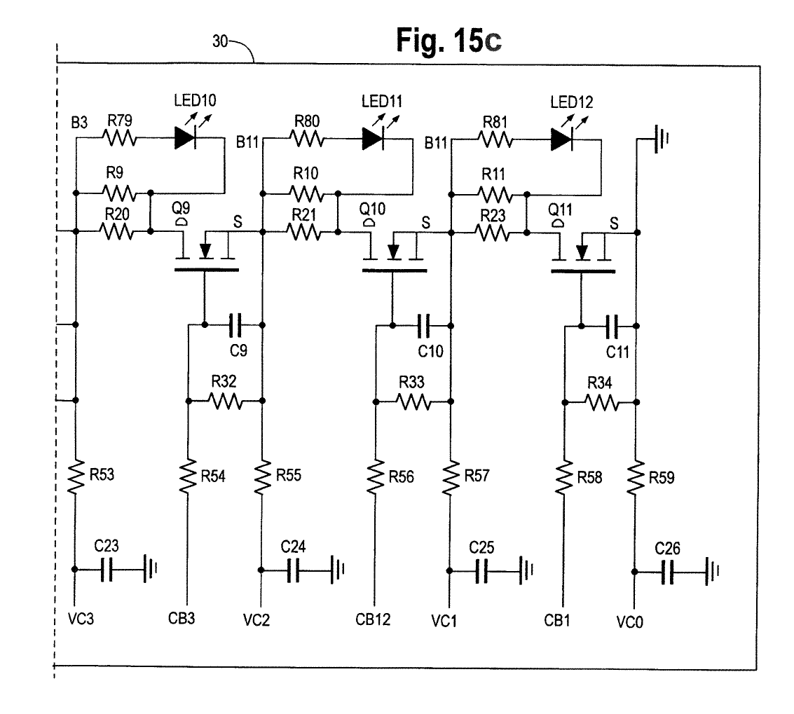

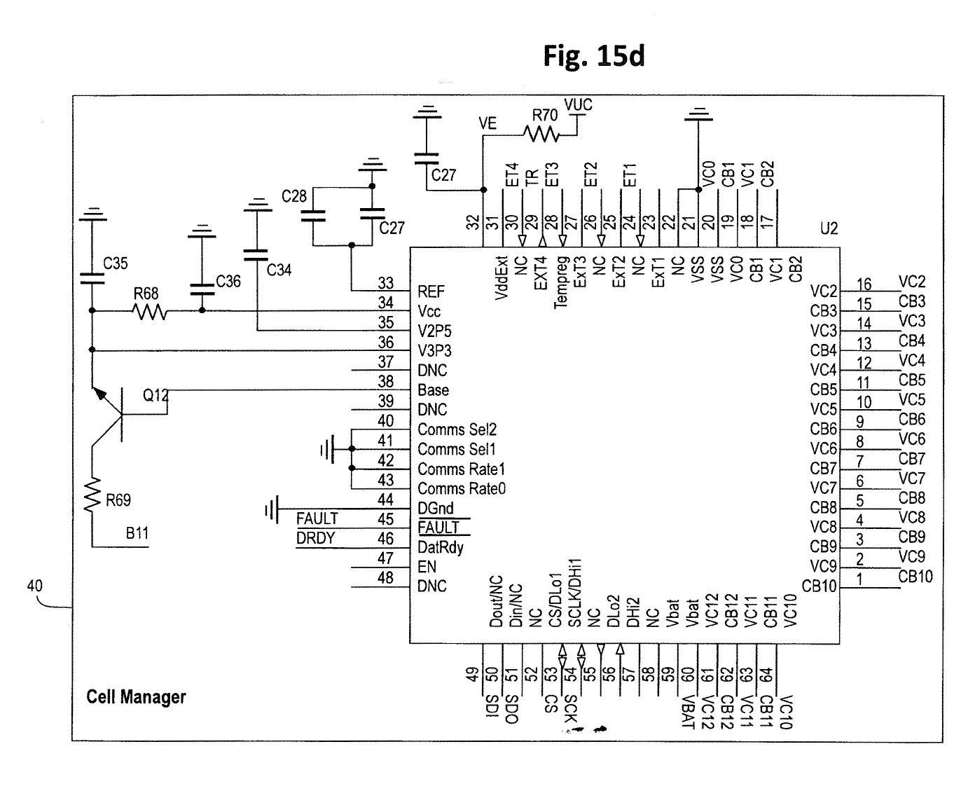

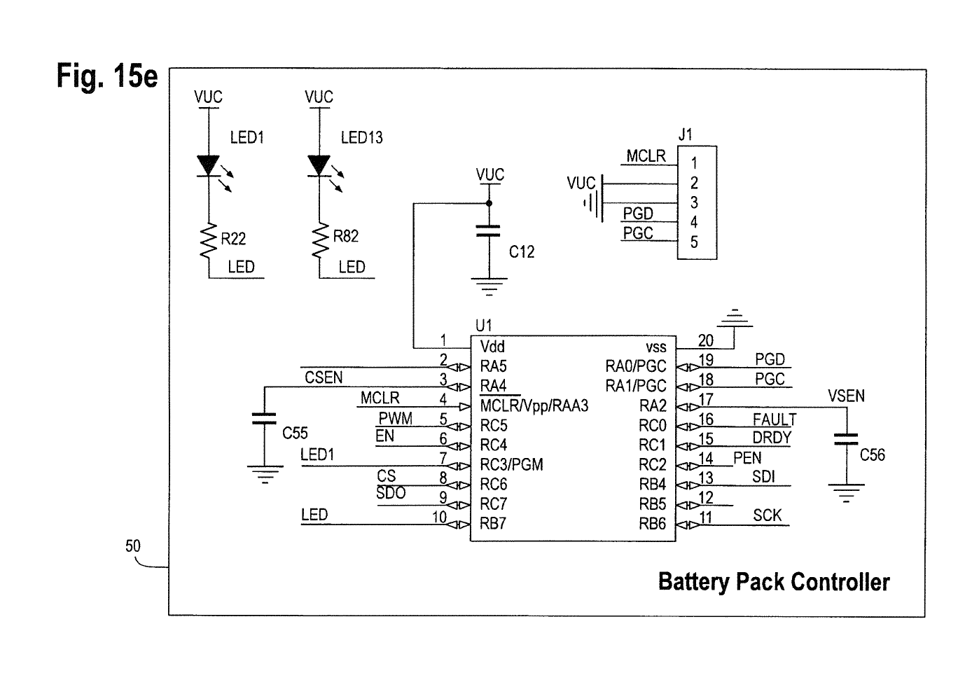

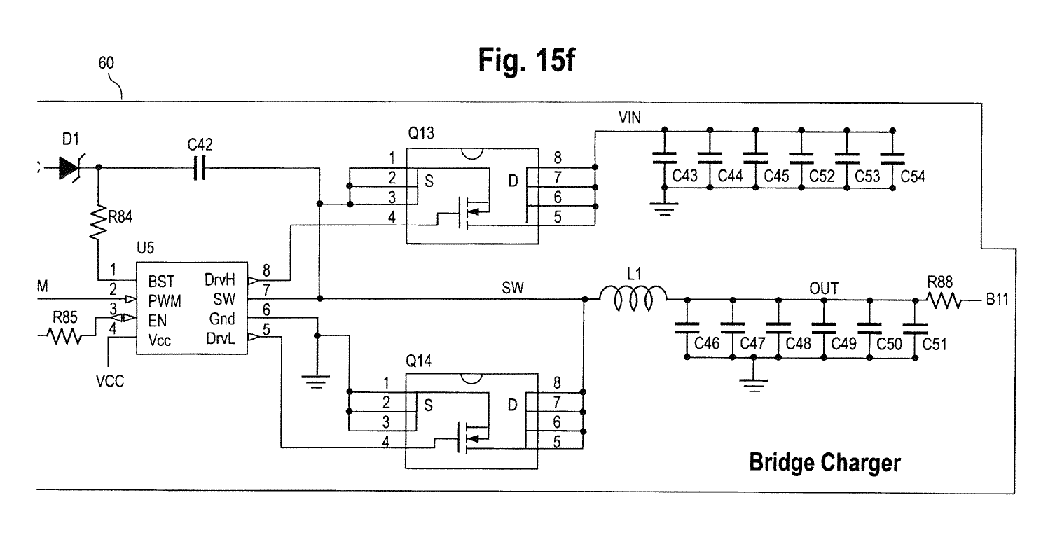

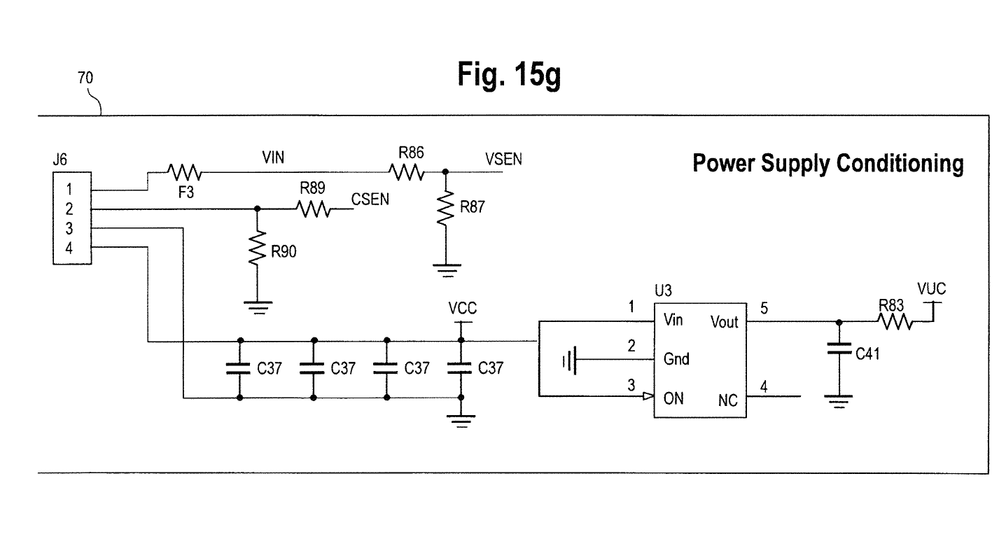

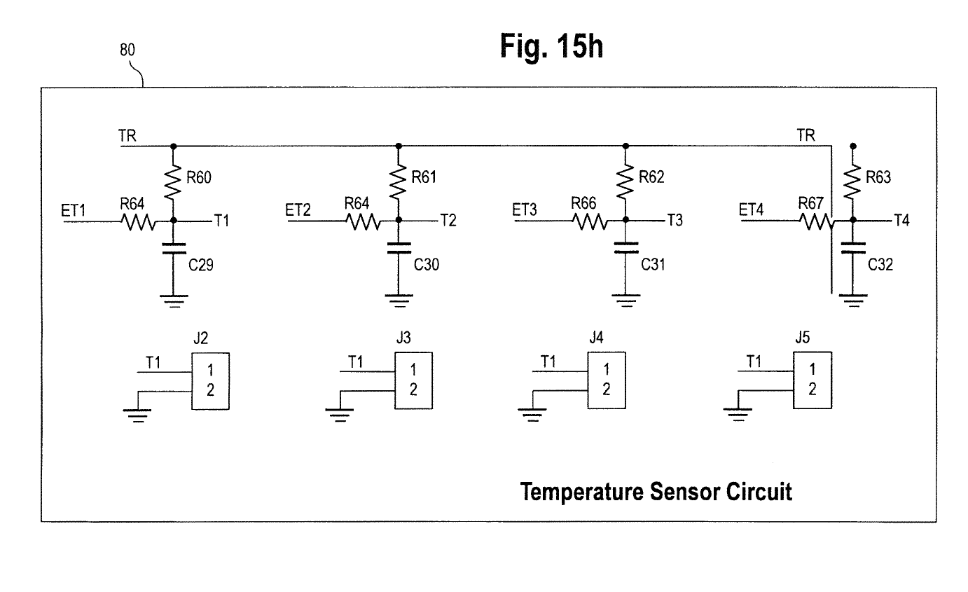

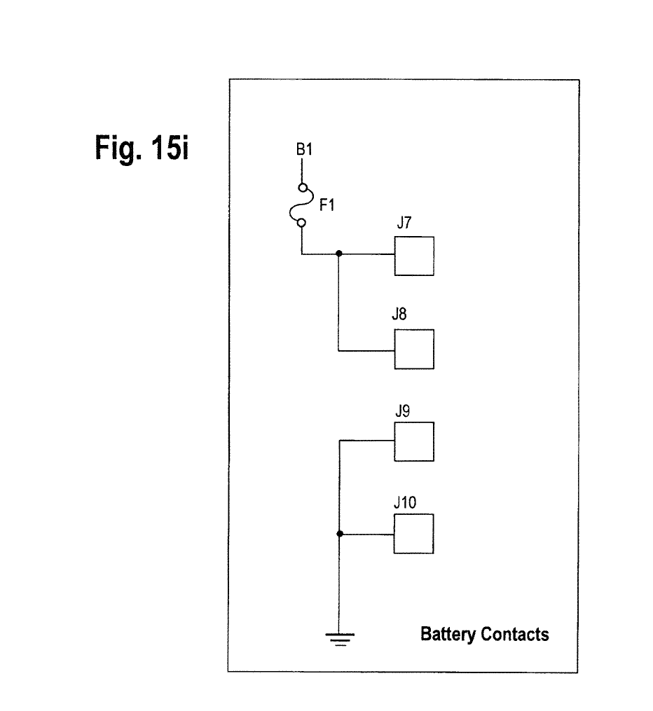

Finally, FIGS. 15a-i shows another preferred embodiment of the components of the controller 20 and related circuitry for charge-management and active cell balancing. Specifically, this figure shows a schematic representation of one preferred embodiment of the battery management circuit. Of course, there are other embodiments which can constitute the controller of the present disclosure, and this example should not limit the present invention. In this embodiment, the main components of the controller include cell balancing network 30, cell manager 40, battery pack controller 50, bridge charger 60, power supply conditioning 70, and temperature sensing circuit 80. These components of this example controller 20 may be further explained as follows:

Cell Balancing Network 30:

The 11 blocks with Q1-Q11 MOSFET transistors and associated components are the Battery balancing circuits. All battery cells in the pack are individually connected to the nets B1, B2, B3, B4, B5, B6, B7, B8, B9, B10 and B11.

The balancing network is key to maintaining a constant and uniform charge on the batteries that comprise the pack. If any of the cells show a charge lower than a predetermined value, the corresponding MOSFETs for the other cells are tuned-on and the charge differential is “bled”. In other words, the balancing circuits will reduce the charge of the cells with the highest state of charge until all the cells have approximately an equal charge. The calculation of the individual cell charge state can vary depending on the battery type and implementation and can be quite complex.

Cell Manager 40:

U2 is a battery cell charge manager. This IC (integrated circuit) is responsible for measuring the voltage on each cell and executing a predetermined balancing algorithm. In addition, the IC is tasked with measuring the temperature and other important parameters of the battery pack. Q12 with associated resistor R69 performs a function of a voltage regulator. The other components are associated with the correct hardware implementation of U2.

Battery Pack Controller 50:

U1 is a processor controlling a battery pack. Unlike battery packs meant for portable products, the battery pack of the present invention is managed differently. The processor tries to maintain a predetermined charge state for each of the cells. It has direct control over the charger circuit and can supply a variable-level charge current to the battery cells.

Bridge Charger 60:

Q13, Q14—MOSFETs, U5 half-bridge driver, LI inductor, C46, C47, C48, C49, C50, C51 filter capacitors, C43, C44, C45, C52, C53, C54 power decoupling capacitors and other associated components comprise a MOSFET bridge that is used as a switch-mode battery pack charger circuit.

The charging bridge current supplied to battery pack constantly varies with the pack state of charge. When the battery pack reaches a predetermined charge (this usually happens at very low level of audio), the charging bridge may be completely disabled. The bridge current is increased as the level of charge drops, so as to maintain a constant charge.

Power Supply Conditioning 70:

J6 is connected to the AC-DC power supply. The power supply provides power that is substantially equal to the audio power needs, but averaged over a long time constant. The battery bank (pack) is utilized as a high energy storage medium to equalize audio power needs. The circuit also contains C37, C38, C39, and C40 decoupling capacitors, R86, R87 and R89, R90 voltage dividers for voltage sensing and F3 resistor used as a fuse. U3/C41 is a voltage regulator for the microcontroller.

Temperature Sensing Circuit 80:

Battery temperature is constantly monitored with thermistors connected to J2, J3, J4, J5 connectors. R60/R64, R61/R65, R62/R66, R63/R67 are resistors associated with forming voltage dividers for temperature sensing. C29, C30, C31, C32 are filter capacitors for the resulting sensing voltage.

The above description is not intended to limit the meaning of the words used in the following claims that define the invention. Rather, it is contemplated that future modifications in structure, function or result will exist that are not substantial changes and that all such insubstantial changes in what is claimed are intended to be covered by the claims. For instance, instead of an AC to DC power supply, alternative versions of the present disclosure could include a main power supply which accepts a predetermined DC voltage (such as power provided by a vehicle's DC bus or provided via PoE (Power over Ethernet) means carried on Cat 5 wiring) which is connected to a DC voltage corresponding to the desired voltage of the hi-power, non-portable audio amplifier load. Likewise, it will be appreciated by those skilled in the art that various changes, additions, omissions, and modifications can be made to the illustrated embodiments without departing from the spirit of the present disclosure. All such modifications and changes are intended to be covered by the following claims.

We claim:

1. A circuit for providing power from a continuously replenished battery pack made up of a plurality of batteries to a non-portable, hi-power non-portable audio amplifier comprising:
a) a battery pack connected directly and providing the only power source to the non-portable, hi-power non-portable audio amplifier;
b) a mains-derived power supply connected to and continuously replenishing the battery pack, so as to enable the battery pack to continuously supply energy to the hi-power non-portable audio amplifier at a level in excess of the capacity of the mains-derived power-supply; and
c) a controller operatively connected to at least the battery pack for maintaining a substantially constant charge level in the battery over an extended period of time.

2. The circuit of claim 1, wherein the mains-derived power supply is an AC to DC power supply.

3. The circuit of claim 1 wherein the battery pack is an chemical battery pack.

4. The circuit of claim 1, wherein the battery pack comprises an array of lithium-based rechargeable batteries.

5. The circuit of claim 1 wherein the controller is operatively connected to at least the battery pack and maintains a substantially constant charge level for each battery within the battery pack for each battery over a period of at least one minute in response to load in excess of the maximum capacity of the mains power supply.

6. The circuit of claim 1, wherein the controller operatively connected to at least the battery pack maintains a substantially constant charge level for each battery within the battery pack over a period of at least ten seconds in response to a load in excess of the maximum capacity of the mains power supply.

7. The circuit of claim 1, wherein the controller operatively connected to at least the battery pack maintains a charge level of at least 10% of the absolute charge capacity of each battery within the battery pack over an extended period of time.

8. The circuit of claim 1, wherein the controller further determines whether each battery within the battery pack for each battery in the battery pack is charged at least to a predetermined level.

9. The circuit of claim 1, wherein the controller further determines whether each battery within the battery pack is charged above a maximum predetermined level.

10. The circuit of claim 1, wherein the controller is further connected to the hi-power, non-portable audio amplifier load.

11. The circuit of claim 1 wherein the hi-power, non-portable audio amplifier load is an amplifier which includes electronic switching elements.

12. The circuit of claim 1 wherein the hi-power, non-portable audio amplifier load is an amplifier which includes MOSFETs.

13. The circuit of claim 8, wherein the controller increases power input to from the mains power supply to each battery within the battery pack when the that particular battery is not charged to at least a predetermined level.

14. The circuit of claim 8, wherein the controller limits the hi-power, non-portable audio amplifier load when the battery pack is not charged to at least a predetermined level.

15. The circuit of claim 9, wherein the controller limits input to the battery pack when the battery pack is charged above a maximum predetermined level.

16. A circuit for providing power from a mains power supply feeding a battery pack made up of a plurality of battery cells in order to supply an appropriate rail voltage at the same time for a high-power, non-portable audio amplifier load comprising:
a) a non-portable, hi-power non-portable audio amplifier including an amplifier bridge,
b) a battery pack providing the sole power connection to the hi-power non-portable audio amplifier;
c) a mains-derived power supply connected to and continuously replenishing the battery pack, so as to enable the battery pack to continuously supply energy to the hi-power non-portable audio amplifier at a level in excess of the capacity of the mains-derived power-supply; and
d) a controller operatively connected to at least the battery pack and the amplifier bridge for maintaining a substantially constant charge level in the battery over an extended period of time and for measuring power draw from the high-power, non-portable audio amplifier load against the mains-derived power supply to determine the availability of power for recharging the battery pack.
